(19) United States
(12) Patent Application Publication
(10) Pub. No.: US 2011/0057660 A1
(43) Pub. Date: Mar. 10, 2011

(54) CURRENT LEAKAGE DETECTOR OF CONSTRUCTION MACHINE

(75) Inventor: Masayuki KAGOSHIMA, Hiroshima-shi (JP)

(73) Assignee: KOBELCO CONSTRUCTION MACHINERY CO., LTD., Hiroshima-shi (JP)

(21) Appl. No.: 12/859,832

(22) Filed: Aug. 20, 2010

(30) Foreign Application Priority Data
Sep. 7, 2009 (JP) 2009-206045

(51) Int. Cl. G01R 31/14

(52) U.S. Cl. 324/509

(57) ABSTRACT

In a construction machine in which a motor is driven by battery power through an inverter in accordance with operation of an operating lever, current-leakage detection signal output means applies a voltage signal, which is adapted for detection of a current leakage, between DC buses connected to the battery and a body of the machine. The applied signal voltage is detected by signal detection means, and the occurrence or non-occurrence of a current leakage is determined based on a crest value of the detected voltage signal. When the operating lever is operated during the determination, the determination is suspended to prevent erroneous detection.

### BACKGROUND OF THE INVENTION

1. Field of the Invention

The present invention relates to a current leakage detector for detecting a current leakage in a motor drive circuit in a construction machine in which a motor is driven by a battery.

2. Description of the Related Art

Hitherto, regarding the technology for detecting, in a battery-loaded vehicle such as a hybrid car, a current leakage in a motor drive circuit that drives a motor by a battery through an inverter, there is known a technique of applying a test voltage, e.g., a sine wave or a pulse wave, between a circuit bus and a body (ground) and measuring a crest value of the test voltage, as disclosed in Patent Document WO2007/007749.

The known technique utilizes the fact that, if a current leakage occurs due to, e.g., an insulation failure, the crest value of the test voltage is reduced to be lower than a reference value due to generation of current leakage resistance. The occurrence of the current leakage is determined when the crest value lower than the reference value is detected.

However, in a construction machine, particularly a shovel (e.g., a hybrid shovel or a battery shovel), in which a motor is driven by battery power, start/stop of operation of an actuator is frequently repeated, and a battery voltage is abruptly varied whenever the operation of the actuator is started and stopped. Accordingly, the crest value of the test voltage also tends to vary upon receiving an influence of the variation in the battery voltage.

For that reason, if the known technique is directly applied to a motor drive circuit in the construction machine, such as the shovel, there is a high possibility of erroneous detection, for example, that a current leakage state is determined in spite of a current leakage being not actually generated.

### SUMMARY OF THE INVENTION

The present invention provides a current leakage detector of a construction machine, which can prevent erroneous detection caused by a variation in a battery voltage, and which can reliably detect a current leakage.

The current leakage detector of the construction machine, according to the present invention, includes a motor drive circuit for driving a motor by a battery through an inverter, signal output means for applying a voltage signal, which is adapted for detection of a current leakage, between the motor drive circuit and a body of the construction machine, signal detection means for detecting the voltage signal applied by the signal output means, motor operation detection means for detecting whether the motor is in an operated state or not, and determination means for determining occurrence or non-occurrence of the current leakage. The determination means determines the occurrence or non-occurrence of the current leakage based on the signal detected by the signal detection means on condition that the non-operated state of the motor is detected by the motor operation detection means.

According to the present invention, since the detection of the current leakage is suspended during the operation of the motor, which causes the variation in the battery voltage, erroneous detection can be prevented and reliable detection of the current leakage can be ensured even in a construction machine, such as a hybrid shovel or a battery shovel, in which the motor operation is frequently started and stopped.

In the above-described constitution of the current leakage detector according to the present invention, preferably, the determination means counts a low crest value time in which a crest value of the voltage signal detected by the signal detection means is not more than a setting value and a high crest value time in which the crest value of the voltage signal detected by the signal detection means exceeds a setting value, determines occurrence of a current leakage state when a count value of the low crest value time is not less than a setting value, determines non-occurrence of the current leakage state when a count value of the high crest value time is not less than a setting value, and interrupts the counting of the low crest value time and the high crest value time when the operation of the motor is detected by the motor operation detection means during the determination.

Further, in the above-described constitution of the current leakage detector according to the present invention, preferably, when the count values of the low crest value time and the high crest value time during a period from start to interruption of the counting are not less than respective setting values, the determination means stores the relevant count values, and when the aforesaid count values are less than the respective setting values, the determination means clears the relevant count values.

Still further, in the above-described constitution of the current leakage detector according to the present invention, preferably, when the interruption of the counting of the low crest value time and the high crest value time continues for a setting time or longer, the determination means clears the relevant count values.

In a preferred embodiment, the determination means counts the low crest value time in which the crest value of the voltage signal detected by the signal detection means is not more than the setting value (i.e., the signal indicating the current leakage state) and the high crest value time in which the crest value of the detected voltage signal is not less than the setting value (i.e., the signal indicating the normal state). If the count value of the low crest value time is not less than the setting value, it is determined that the current leakage state is present, and if the count value of the high crest value time is not less than the setting value, it is determined that the current leakage state is not present. Therefore, the influence of temporary noise can be eliminated and the determination as to the current leakage state or the normal state can be performed with higher reliability.

Moreover, when respective count values of the low crest value time and the high crest value time during the period from start of the counting to its interruption due to the operation of the motor are not less than the setting values, those count values are stored to be ready for restart of the counting after the interruption. If the count values are less than the setting values, those count values are cleared because they are not enough as data for making the determination. In addition, when the interruption of the counting of the low crest value time and the high crest value time continues for the setting time or longer, the count values are cleared on judgment that they are the past data to be discarded. As a result, accuracy in the determination can be increased.

### BRIEF DESCRIPTION OF THE DRAWINGS

FIG. 1 is a block diagram of a drive system and a control system in a hybrid shovel to which the present invention is applied;

FIG. 2 illustrates the system configuration of a current leakage detector for a motor drive circuit according to an embodiment of the present invention; and

FIG. 3 is a flowchart to explain the flow of a determination process in the current leakage detector.

### DESCRIPTION OF THE PREFERRED EMBODIMENTS

In an embodiment described below, the present invention is applied to a hybrid shovel which utilizes engine power and battery power in a combined manner.

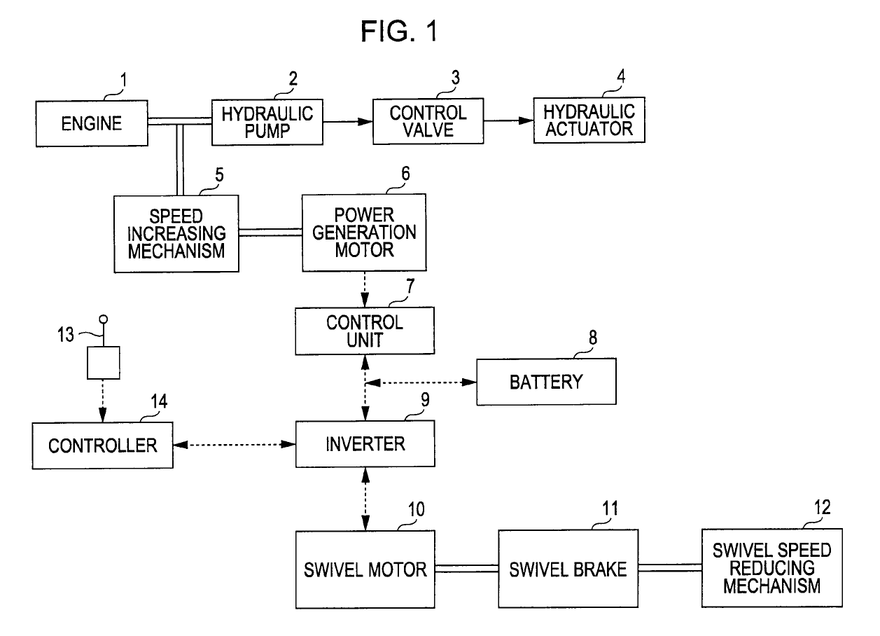

FIG. 1 is a block diagram of a drive system and a control system, which are generally used in the hybrid shovel.

A hydraulic pump 2 is connected to an engine 1, and oil delivered from the hydraulic pump 2 is supplied to a hydraulic actuator 4 (which is representatively illustrated here, although an actual machine includes hydraulic cylinders for a boom, an arm and a bucket and a hydraulic motor for traveling) through a control valve 3.

An output of the engine 1 is applied to a power generation motor 6 through a speed increasing mechanism 5. Electric power produced by the power generation motor 6 is accumulated in a battery 8 through a control unit 7 which controls a voltage and a current. The electric power is further applied to a swivel motor 10 through an inverter 9.

The power generation motor 6 also operates as a motor with the electric power stored in the battery 8, thereby assisting the engine 1 as required.

The swivel motor 10 is provided with a swivel brake 11 for holding the swivel motor 10 in a stopped state. When the swivel brake 11 is in a released state, a rotating force (torque) of the swivel motor 10 is transmitted to an upper swivel structure of the shovel through a swivel speed reducing mechanism 12, whereupon the upper swivel structure is swiveled (rotated) clockwise or counterclockwise.

At that time, a voltage of the battery 8 varies with the rotation of the swivel motor 10. If such a variation in the battery voltage occurs during a later-described process of determining a current leakage, there arises a possibility of erroneous detection.

Reference numeral 13 denotes a swivel operating lever, which serves as one of operating means. In accordance with an operation signal from the operating lever 13, a command signal is output from a controller 14 to the inverter 9, whereupon the swivel motor 10 is controlled.

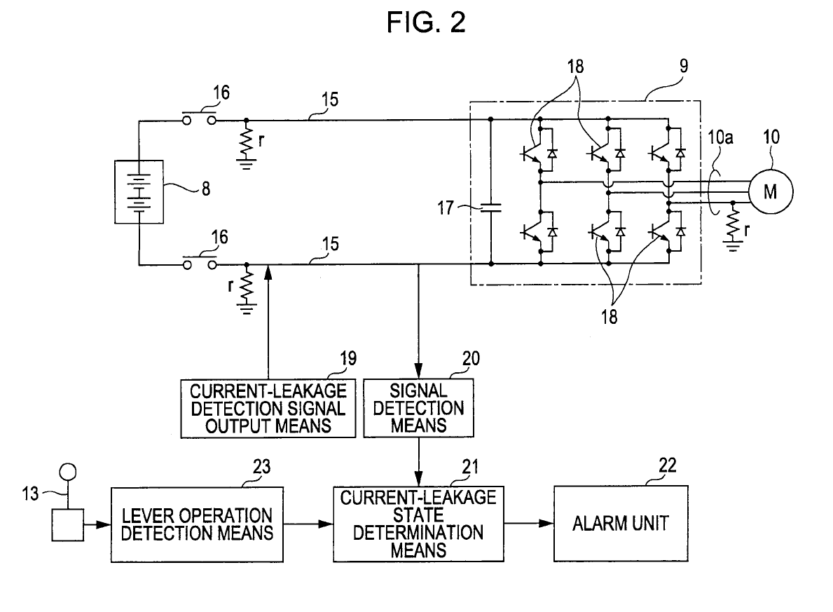

FIG. 2 illustrates the system configuration of a current leakage detector.

The embodiment is constructed so as to detect, in a motor drive circuit for driving the swivel motor 10 by the battery 8 through the inverter 9, a current leakage between the motor drive circuit and a not-shown machine body (ground).

Here, the term “machine body” implies an upper frame of the upper swivel structure in the case of the shovel, the upper frame being grounded through a swivel bearing and a lower traveling structure.

In FIG. 2, reference numerals 15 and 15 denote DC buses of the motor drive circuit, 16 and 16 denote relays (contacts) disposed respectively in the buses 15 and 15 for connection to the battery 8, 17 denotes a capacitor in the inverter 9, 18 denotes a plurality of switching devices, and 10a denotes 3-phase AC lines between the inverter 9 and the swivel motor 10. Further, a reference character r represents current leakage resistance that is generated with a current leakage.

The current leakage detector includes current-leakage detection signal output means 19 for applying a voltage signal (e.g., a pulse voltage at a particular frequency), which is adapted for detection of the current leakage, to the motor drive circuit, specifically between the DC buses 15, 15 and the body, for example, signal detection means 20 for detecting the applied voltage signal, current-leakage state determination means 21, an alarm unit 22 for issuing an alarm in accordance with a signal output from the current-leakage state determination means 21 when the occurrence of the current leakage is determined, and lever operation detection means 23 for detecting whether the operating lever 13 is operated or not.

The current-leakage state determination means 21 determines the occurrence or non-occurrence of the current leakage based on a crest value of the signal detected by the signal detection means 20 and on whether the swivel motor 10 is operated or not.

As described above, the swivel motor 10 is operated in accordance with the operation of the operating lever 13. This implies that whether the swivel motor 10 is operated or not can be indirectly detected by detecting whether the operating lever 13 is operated or not.

In the current leakage detector according to the embodiment, therefore, whether the operating lever 13 is operated or not is detected by using the lever operation detection means (e.g., a potentiometer) 23 instead of detecting the motor operation state, and the detected signal is input, as a motor operation state signal, to the current-leakage state determination means 21.

Taking into account that the crest value of the detected signal (in the form of a pulse voltage) does not exceed a setting value in the current leakage state, but it exceeds the setting value in the current non-leakage state, the current-leakage state determination means 21 counts a time in which the crest value does not exceed the setting value (called a “low crest value time”) and a time in which the crest value exceeds the setting value (called a “high crest value time”). Then, the current-leakage state determination means 21 determines that the state current leakage is present, when a count value of the low crest value time is not less than a setting value for the count value of the low crest value time, and determines that the current leakage state is not present (i.e., current non-leakage state=normal state), when a count value of the high crest value time is not less than a setting value for the count value of the high crest value time.

Be it noted that the low crest value time and the high crest value time may be each a time during which the low crest value or the high crest value is continuously detected, or a time derived from the numbers of pulses representing the low crest value or the high crest value.

When the lever operation (i.e., the operation of the motor) is detected by the lever operation detection means 23 during the determination, the counting of the low crest value time and the high crest value time is interrupted (namely, the detection of the current leakage is suspended) in consideration of a risk that erroneous detection may occur due to a variation in the battery voltage.

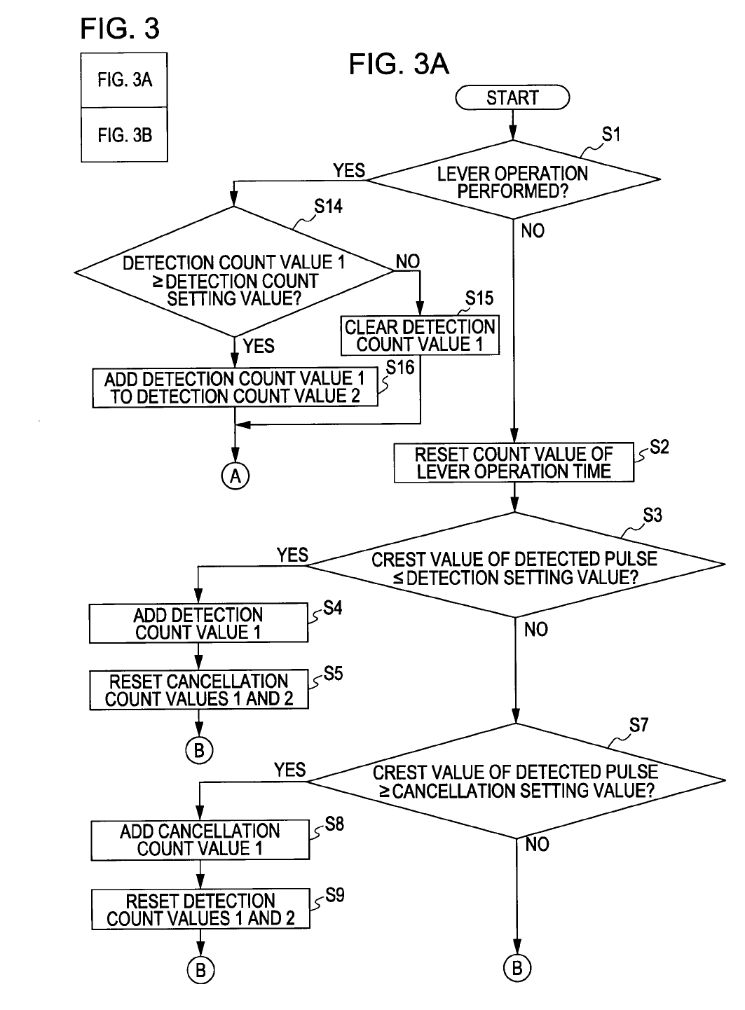

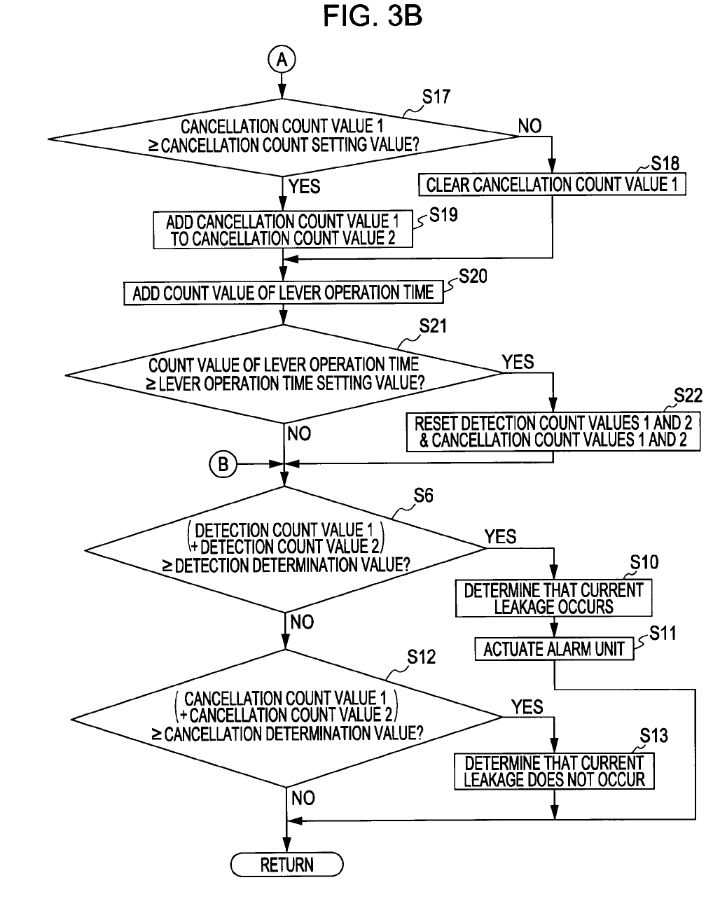

FIG. 3 illustrates details of the current leakage determination process, which is executed by the current-leakage state determination means 21.

### A. When Lever Operation is not Performed During Determination

In step S1, whether the lever operation is performed or not is determined. If there is no lever operation (“NO”), the determination process advances to a current leakage detection flow, and if there is the lever operation (“YES”), the determination process advances to a current-leakage detection suspension flow.

In the flow of FIG. 3, the term “count value” implies a count value of the low crest value time or the high crest value time, the term “detection count value” implies a count value of the low crest value time, and the term “detection setting value” implies a threshold set for determining whether the detected crest value is the low crest value or not. Further, the term “cancellation count value” implies a count value of the high crest value time, and the term “cancellation setting value” implies a threshold set for determining whether the detected crest value is the high crest value or not.

Regarding the count value, the term “count value 1” implies a current count value, and the term “count value 2” implies a past count value that has been stored. Further, the term “detection count setting value” implies a threshold set for the detection count value, and the term “cancellation count setting value” implies a threshold set for the cancellation count value.

In the current leakage detection flow, a count value of a lever operation time is first reset in step S2. The flow then shifts to step S3.

In step S3, it is determined whether the crest value of the detected pulse is not more than the detection setting value (i.e., whether it indicates the current leakage state). If the determination result is “YES” (i.e., if the current leakage state is indicated), the detection count value 1 is added in step S4 to count the low crest value time, and the cancellation count values 1 and 2 are reset in step S5. Thereafter, the flow shifts to step S6.

On the other hand, if the determination result in step S3 is “NO” (i.e., crest value of detected pulse>detection setting value), the flow shifts to step S7 in which it is determined whether the crest value of the detected pulse is not less than the cancellation setting value. If the determination result in step S7 is “YES”, the flow advances in order of step S8, step S9, and step S6. If the determination result in step S7 is “NO”, the flow directly advances to step S6.

In step S8, the cancellation count value 1 is added to count the high crest value time. In step S9, the detection count values 1 and 2 are reset.

In step S6, the count value of the low crest value time (i.e., the total value of the detection count values 1 and 2) is compared with a detection determination value that is a count value as a reference for determining the current leakage state. If the former is not less than the latter, it is determined in step S10 that the current leakage occurs. The alarm unit 23 in FIG. 2 is actuated in step S11 so as to notify an operator of the occurrence of the current leakage. Thereafter, the flow returns to step S1.

On the other hand, if the count value of the low crest value time is less than the detection determination value (if the determination result in step S6 is “NO”), the count value of the high crest value time (i.e., the total value of the cancellation count values 1 and 2) is compared in step S12 with a cancellation determination value that serves as a reference for determining cancellation of the detection of the current leakage. If the former is not less than the latter (i.e., if the determination result in step S12 is “YES”), it is determined in step S13 that the current leakage does not occur. Thereafter, the flow returns to step S1. If the determination result in step S12 is “NO”, the flow directly returns to step S1.

### B. When Lever Operation is Performed During Determination

If the determination result in step S1 is “YES” (i.e., if the lever operation is performed), the detection of the current leakage is interrupted as follows. First, in step S14, it is determined whether the count value of the low crest value time during a period from start to interruption of the counting (i.e., the detection count value 1) is not less than the detection count setting value that serves as a threshold. If the determination result in step S14 is “NO” (i.e., if the former is less than the latter), the relevant count value is cleared in step S15. If the determination result in step S14 is “YES” (i.e., if the former is not less than the latter), the count value is stored (namely, the detection count value 1 is added to the detection count value 2) in step S16.

In subsequent step S17, it is determined whether the count value of the high crest value time during the period from start to interruption of the counting (i.e., the cancellation count value 1) is not less than the cancellation count setting value that serves as a threshold. If the determination result in step S17 is “NO” (i.e., if the former is less than the latter), the relevant cancellation count value 1 is cleared in step S18. If the determination result in step S17 is “YES” (i.e., if the former is not less than the latter), the count value is stored (namely, the cancellation count value 1 is added to the cancellation count value 2) in step S19.

In step S20, the count value of the lever operation time is added. In step S21, the resulting count value is compared with a lever operation time setting value that is a threshold set for the lever operation time.

If the determination result in step S21 is “YES” (i.e., count value of lever operation time≧lever operation time setting value), the detection count values 1 and 2 and the cancellation count values 1 and 2 are reset in step S22, following which the flow shifts to step S6. If the determination result in step S21 is “NO”, the flow directly shifts to step S6.

Thus, according to the current leakage detector of the embodiment, the detection of the current leakage is suspended during the operation of the motor 10, which causes the variation in the battery voltage. Therefore, erroneous detection can be prevented and reliable detection of the current leakage can be ensured even in the construction machine, such as the hybrid shovel or the battery shovel, in which the motor operation is frequently started and stopped and for which the embodiment has been described above.

Further, in steps S4 to S12, the low crest value time in which the crest value of the detected pulse voltage is not more than the setting value (i.e., the signal indicating the current leakage state) and the high crest value time in which the crest value of the detected pulse voltage is not less than the setting value (i.e., the signal indicating the normal state) are counted. If the count value of the low crest value time is not less than the setting value, it is determined that the current leakage state is present, and if the count value of the high crest value time is not less than the setting value, it is determined that the current leakage state is not present. Therefore, the influence of temporary noise can be eliminated and the determination as to the current leakage state or the normal state can be performed with higher reliability.

Moreover, in steps S14 to S21, if respective count values of the low crest value time and the high crest value time during the period from start of the counting to its interruption due to the operation of the motor are not less than the setting values, those count values are stored to be ready for restart of the counting after the interruption. If the count values are less than the setting values, those count values are cleared because they are not enough as data for making the determination. In addition, if the interruption of the counting of the low crest value time and the high crest value time continues for a setting time or longer, the count values are cleared on judgment that they are the past data to be discarded. As a result, accuracy in the determination can be increased.

### Other Embodiments

(1) When the power generation motor 6 operates as a motor (to assist the engine) with the battery power, the battery voltage also varies, thus causing a possibility of erroneous detection of the current leakage. Therefore, the determination as to the current leakage may be suspended during the operation of the power generation motor 6.

(2) The present invention can be applied to not only the hybrid shovel, but also to a battery shovel employing only a battery as a power source and other battery-loaded construction machines than the shovels in a similar manner to that in the embodiment described above.

Although the invention has been described with reference to the preferred embodiments in the attached figures, it is noted that equivalents may be employed and substitutions made herein without departing from the scope of the invention as recited in the claims.

What is claimed is:

1. A current leakage detector of a construction machine comprising:
a motor drive circuit for driving a motor by a battery through an inverter;
signal output means for applying a voltage signal, which is adapted for detection of a current leakage, between the motor drive circuit and a body of the construction machine;
signal detection means for detecting the voltage signal applied by the signal output means;
motor operation detection means for detecting whether the motor is in an operated state or not; and
determination means for determining occurrence or non-occurrence of the current leakage, the determination means determining the occurrence or non-occurrence of the current leakage based on the signal detected by the signal detection means on condition that the non-operated state of the motor is detected by the motor operation detection means.

2. The current leakage detector of the construction machine according to claim 1, wherein the determination means counts a low crest value time in which a crest value of the voltage signal detected by the signal detection means is not more than a setting value and a high crest value time in which the crest value of the voltage signal detected by the signal detection means exceeds a setting value, determines occurrence of a current leakage state when a count value of the low crest value time is not less than a setting value, determines non-occurrence of the current leakage state when a count value of the high crest value time is not less than a setting value, and interrupts the counting of the low crest value time and the high crest value time when the operation of the motor is detected by the motor operation detection means during the determination.

3. The current leakage detector of the construction machine according to claim 2, wherein when the count values of the low crest value time and the high crest value time during a period from start to interruption of the counting are not less than respective setting values, the determination means stores the relevant count values, and when the aforesaid count values are less than the respective setting values, the determination means clears the relevant count values.

4. The current leakage detector of the construction machine according to claim 2, wherein when the interruption of the counting of the low crest value time and the high crest value time continues for a setting time or longer, the determination means clears the relevant count values.
